(19) United States
(12) Patent Application Publication
(10) Pub. No.: US 2006/0137740 A1
(43) Pub. Date: Jun. 29, 2006

(54) Photovoltaic cell and method of manufacturing the same

(75) Inventors: Young-jun Park, Suwon-si (KR); Sang-cheol Park, Seoul (KR); Won-cheol Jung, Seoul (KR); Jung-gyu Nam, Yongin-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Suwon-si (KR)

(21) Appl. No.: 11/291,896

(22) Filed: Dec. 2, 2005

(30) Foreign Application Priority Data
Dec. 27, 2004 (KR) 10-2004-0112902

(51) Int. Cl. H01L 31/00

(52) U.S. Cl. 136/263; 136/252

(57) ABSTRACT

A photovoltaic cell having an improved semiconductor layer and a method of manufacturing the same are provided. The photovoltaic cell includes a first electrode and a second electrode disposed opposite each other and spaced a predetermined distance apart from each other; and an oxide semiconductor layer interposed between the first and second electrodes and disposed on the first electrode. The oxide semiconductor layer includes a base and a plurality of rods, each of which vertically extends from the base and provides fine apertures, and the base and the rods are integrally formed. As the surface area of the oxide semiconductor layer increases, the photovoltaic cell achieves a high electron transfer efficiency and a high photoelectric conversion efficiency.

### CROSS-REFERENCE TO RELATED PATENT APPLICATION

This application claims the benefit of Korean Patent Application No. 10-2004-0112902, filed on Dec. 27, 2004, in the Korean Intellectual Property Office, the disclosure of which is incorporated herein in its entirety by reference.

### BACKGROUND OF THE DISCLOSURE

1. Field of the Disclosure

The present disclosure relates to a photovoltaic cell, more particularly, to a photovoltaic cell, which is enhanced in electron transfer efficiency and electron collection efficiency, and a method of manufacturing the same.

2. Description of the Related Art

A conventional dye-sensitized photovoltaic cell is a photoelectrochemical solar battery that makes use of an oxide semiconductor material, which comprises photosensitive dye molecules and nanoparticle titanium oxide. The dye-sensitized photovoltaic cell can be produced at lower cost than a conventional silicon solar cell and can be applied to glass windows for outer walls of buildings or glass greenhouses owing to its transparent electrodes. Thus, a number of studies have been made concerning dye-sensitized photovoltaic cells.

U.S. Pat. No. 5,350,644, issued to Tohru Den, proposes a photovoltaic cell in which a charge transfer layer includes acicular crystals.

The charge transfer layer having the acicular crystals provides high photoelectric conversion efficiency to enable the efficient transfer of charges, in comparison to a conventional charge transfer layer in which fine titanium oxide particles are bonded.

However, the charge transfer layer having the acicular crystals still retains boundaries between electrodes and the acicular crystals, which become obstacles to the transport of electrons. Even though it is necessary to uniformly distribute acicular crystals to efficiently collect electrons, conventional processes appear to be reaching the technical limit for attaining the uniform distribution of the acicular crystals.

### SUMMARY OF THE DISCLOSURE

The present invention may provide a photovoltaic cell, in which acicular crystals are uniformly distributed, and a method of manufacturing the same.

Also, the present invention may provide a photovoltaic cell having enhanced electron transfer efficiency and photoelectric conversion efficiency and a method of manufacturing the same.

According to an embodiment of the present invention, there is provided a photovoltaic cell including a first electrode and a second electrode disposed opposite each other and spaced a predetermined distance apart from each other; and an oxide semiconductor layer interposed between the first and second electrodes and disposed on the first electrode. Herein, the oxide semiconductor layer includes a base and a plurality of rods, each of which vertically extends from the base and provides fine apertures, and the base and the rods are integrally formed.

In an embodiment, the base and the rods of the oxide semiconductor layer may be formed of the same material.

In another embodiment, each of the rods may have a porous structure with a surface which has a plurality of cavities. In a further embodiment, a plurality of protrusions may be formed on the surface of each of the rods.

In an embodiment, the first electrode may include a first substrate; and a first transparent conductive layer disposed on one surface of the first substrate, and the second electrode may include a second substrate; a second transparent conductive layer disposed on one surface of the second substrate; and a noble metal thin layer disposed on an inner surface of the second transparent conductive layer.

In an embodiment, the base and the rods may be formed of SnO₂, TiO₂, or ZnO.

According to another embodiment of the present invention, there is provided a method of manufacturing a photovoltaic cell. The method includes forming a transparent conductive layer on a substrate; forming a base on the transparent conductive layer using an oxide semiconductor material to a predetermined thickness; forming a template layer on the base, the template layer having a plurality of wells that expose the surface of the base; forming a plurality of rods in the wells by filling an oxide semiconductor material in the wells; and forming an oxide semiconductor layer by removing the template layer, and the oxide semiconductor layer including the rods formed on the base.

In an embodiment, the template layer may be formed of a photoresist material.

In another embodiment, the method may further include injecting fine particles or balls into the wells before forming the rods in the wells; and removing the fine particles or balls together while removing the template layer.

In yet another embodiment, the template layer may be formed of a material containing a plurality of distributed fine particles or balls. The fine particles or balls may be formed of polystyrene or silica.

### BRIEF DESCRIPTION OF THE DRAWINGS

The above and other features and advantages of the present invention will be apparent from exemplary embodiments thereof with reference to the attached drawings in which:

FIG. 1 is a cross-sectional view of a photovoltaic cell according to an exemplary embodiment of the present invention;

FIG. 2 is an exploded view of a main portion of the photovoltaic cell shown in FIG. 1;

FIG. 3A is an exploded view of an oxide semiconductor layer having a plurality of rods in a photovoltaic cell according to another exemplary embodiment of the present invention;

FIG. 3B is an exploded view of an oxide semiconductor layer having a plurality of rods in a photovoltaic cell according to yet another exemplary embodiment of the present invention;

FIGS. 4A through 4F are cross-sectional views illustrating operations for forming the photovoltaic cell shown in FIGS. 1 and 2;

FIGS. 5A through 5C are cross-sectional views illustrating operations for forming the photovoltaic cell shown in FIG. 3A; and

FIGS. 6A through 6E are cross-sectional views illustrating operations for forming the photovoltaic cell shown in FIG. 3B.

### DETAILED DESCRIPTION OF THE EXEMPLARY EMBODIMENTS

A photovoltaic cell and a method of manufacturing the same will now be described more fully hereinafter with reference to the accompanying drawings, in which exemplary embodiments of the invention are shown.

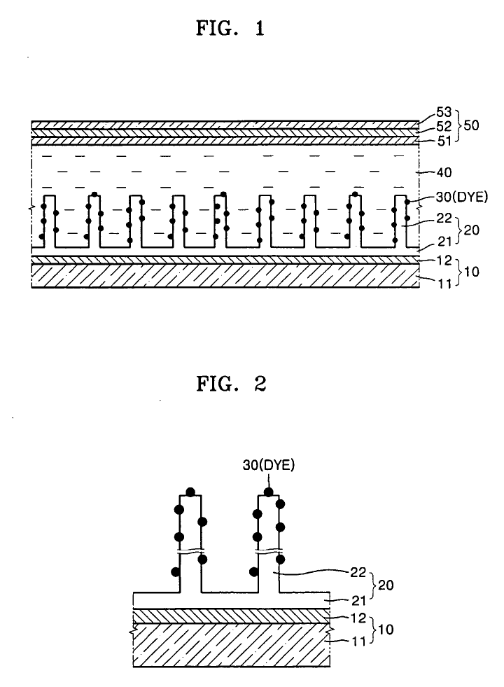

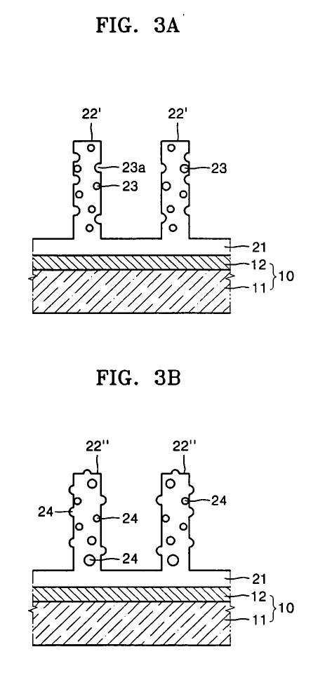

FIG. 1 is a cross-sectional view of a photovoltaic cell according to an exemplary embodiment of the present invention, and FIG. 2 is an exploded view of a main portion of the photovoltaic cell shown in FIG. 1.

Referring to FIGS. 1 and 2, the photovoltaic cell includes a sandwich of a first electrode structure 10 (hereinafter, a first electrode) and a second electrode structure 50 (hereinafter, a second electrode) separated by an oxidation-reduction electrolytic solution 40.

The first electrode 10 includes a first substrate 11 and a first transparent conductive layer 12, which is disposed on the first substrate 11. An oxide semiconductor layer 20, which is utilized in the present invention, is disposed on the first transparent conductive layer 12. The oxide semiconductor layer 20 includes a base 21, which is disposed on the first transparent conductive layer 12, and a plurality of rods 22, which extend from the base 21 in a vertical direction. The rods 22, which are fixed to the base 21, are clustered close together to greatly expand the surface area onto which a dye 30 is absorbed. Also, the rods 22 provide fine apertures into which the electrolytic solution 40 permeates. The dye 30 for absorbing light energy is absorbed onto the surface of the oxide semiconductor layer 20, specifically, the surfaces of the rods 22.

The second electrode 50 disposed on the electrolytic solution 40 includes a noble metal thin layer 51, which is in contact with the electrolytic solution 40 and formed of, for example, platinum, a second transparent conductive layer 52 on which the noble metal thin layer 51 is coated, and a second substrate 53, which supports the second transparent conductive layer 52.

The first substrate 11 may be formed of a material, which has good optical transmittance and can be used as a cathode for a solar battery. For example, the first substrate 11 may be formed of glass, polyethylene terephthalate (PET), polyethylene naphthalate (PEN), or polycarbonate (PC). The first conductive layer 12 may be formed of a transparent conductive material, such as indium tin oxide (ITO) or fluorine tin oxide (FTO).

The second substrate 53 may be formed of glass or a plastic such as PET, PEN, PC, PP, PI, or TAC. The second conductive layer 52 disposed on the second substrate 53 may be formed of ITO or FTO.

The noble metal thin layer 51 disposed on one surface of the second conductive layer 52 for an opposing electrode may be formed using an H₂PtCl₆ solution dissolved in an organic solvent (e.g., MeOH, EtOH, or IPA) through a wet coating process, such as a spin coating process, a dip coating process, or a flow coating process. In another embodiment, the noble metal thin layer 51 may be formed by performing an annealing process at a temperature of about 400° C. or higher in an air or O₂ atmosphere or by performing an electroplating process or a physical vapor deposition (PVD) process, such as sputtering or e-beam (electron-beam) deposition.

The oxidation-reduction electrolytic solution 140 is made by dissolving 0.5-M tetrapropylammonium iodide or 0.8-M lithium iodide (Lil) along with 0.05-M iodine (I₂) as an I-source in acetonitrille.

As described above, the oxide semiconductor layer 20 according to the present invention includes the base 21 and the plurality of rods 22, which are directly fixed to the base 21 and integrally connected to the base 21. Since the oxide semiconductor layer 20 is fixed to the first electrode 10 by the base 21 that is directly coated on the underlying second transparent electrode 12, the present invention can be freed from problems related to an interfacial surface between the oxide semiconductor layer 20 and the first electrode 10. That is, in the present invention, the rods 22 to which the dye 30 is absorbed are directly fixed to the first electrode 10 in a physical manner, thus the interfacial surface between the oxide semiconductor layer 20 and the first electrode 10 causes no problem. In particular, because it is possible to uniformly control the density of the rods 22, the surface area of the oxide semiconductor layer 20 is greatly increased to provide a sufficient area onto which the dye 30 is absorbed and with which the electrolytic solution 4 comes into contact. As a result, photoelectric conversion efficiency can be dramatically enhanced.

In order to further elevate the performance of the photovoltaic cell, the surface area of the oxide semiconductor layer 20 can be further expanded by improving the structures of the rods 22 as described in the following embodiments.

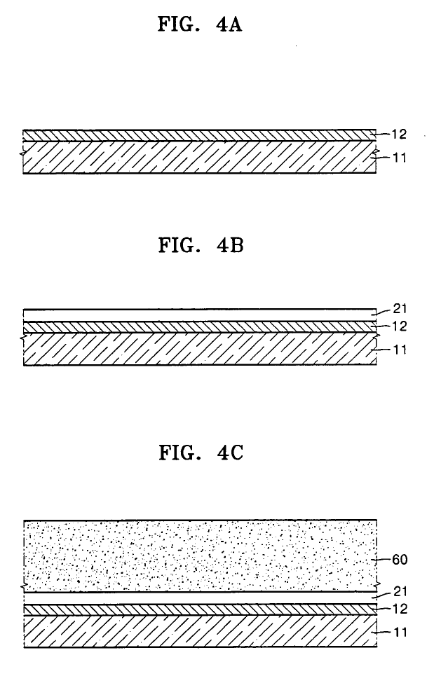

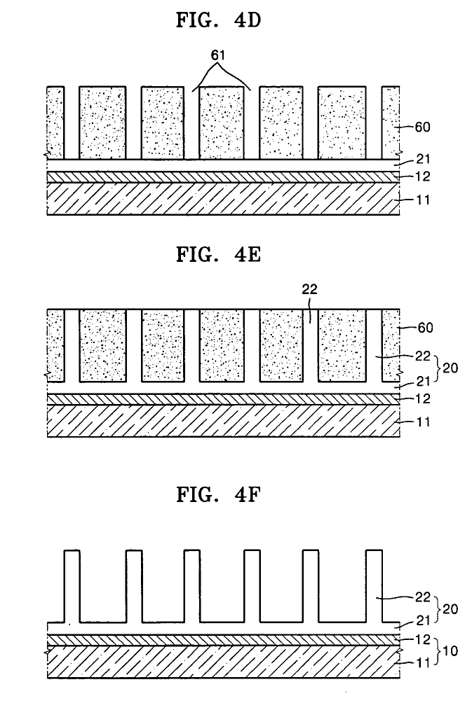

FIGS. 3A and 3B illustrates an oxide semiconductor layer of a photovoltaic cell according to further embodiments of the present invention.

Referring to FIG. 3A, a rod 22′, which is formed on a base 21 in a vertical direction, has a porous structure. That is, the rod 22′ has a plurality of cavities 23 so that an electrolytic solution (40 of FIG. 1) can permeate the cavities 23.

Referring to FIG. 3B, a rod 22″, which is formed on a base 21 in a vertical direction, has a rugged outer surface on which a plurality of protrusions 24 are formed. That is, the protrusions 24 are formed on the rod 22″ to expand the surface area of the oxide semiconductor layer (20 of FIG. 1), onto which the dye (30 of FIG. 1) is absorbed and with which the electrolytic solution 40 is in contact.

Hereinafter, a method of manufacturing a photovoltaic cell according to exemplary embodiments of the present invention will be described. The method is directed at improving the structure of an oxide semiconductor layer, and a process of forming the oxide semiconductor layer on a first electrode will be primarily described. Since a second electrode can be formed by a known method, a process of forming the second electrode is omitted. The second electrode and the process of forming the same do not limit the technical scope of the present invention.

### Embodiment 1

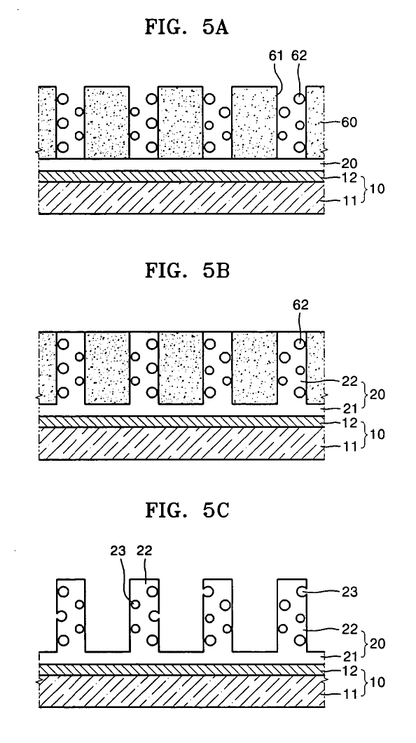

Referring to FIG. 4A, a transparent conductive layer 12 is formed on a substrate 11. The substrate 11 is formed of glass or a plastic, such as PET, PEN, or PC. The transparent conductive layer 12 is formed by coating ITO or FTO on the substrate 11 to a thickness of about 100 nm using a sputtering process or a vacuum evaporation process.

Referring to FIG. 4B, a base 21 for an oxide semiconductor layer is formed on the conductive layer 12. The base 21 is formed of a transition metal oxide (i.e., an oxide semiconductor material), for example, SnO₂, ZnO, TiO₂, or other electron donative materials. Also, the base 21 is formed using a sputtering process, a vacuum evaporation process, or a printing process to a thickness of about 10 to 100 nm.

Referring to FIG. 4C, a template layer 60 is formed on the base 21. The template layer 60 is formed to a thickness of, for example, about 20 microns, using a spin coating process or other thick layer forming processes. The template layer 60 may be formed of a material that is soluble in a certain solvent. For example, the template layer 60 may be formed of acrylamide (MM), polymethylmethacrylate (PMMA), or PC.

Referring to FIG. 4D, a plurality of wells 61 are formed in the template layer 60 such that the surface of the base 21 is exposed in the bottoms of the wells 61. The method of forming the wells 61 does not limit the technical scope of the present invention. For example, the wells 61 may be formed using a photography process or an e-beam lithography process. The diameter of the wells 61 and the distance between the wells 61 can be appropriately controlled according to design specifications. For instance, the wells 61 have a diameter of about 20 to 200 nm.

Referring to FIG. 4E, an oxide semiconductor material 22 is filled in the wells 61. For this, a TiCl₄ solution is brought into contact with the base 21, which is exposed in the bottoms of the wells 61, for about 3 hours so that rods 22 fixed onto the base 21 are formed due to hydrolysis. Thereafter, the resultant structure is precipitated and then annealed at a temperature of about 50° C. for about 2 hours.

Referring to FIG. 4F, the template layer 60 is removed, thereby forming an oxide semiconductor layer 20, which includes the base 21 and the plurality of rods 22 that are vertically fixed to the base 21. Typically, after the template layer 60 is removed, post-treatment is required. For example, after the template layer 60 is dissolved in a solvent (e.g., NaOH) and removed, the resultant structure may be cleaned using deionized water and then thermally treated in an appropriate method. For instance, the thermal treatment may be performed at a temperature of about 100° C. for about 30 minutes. As a result, the rods 22 can be solidly fixed onto the base 21.

In the above-described process, the oxide semiconductor layer 20 having the plurality of rods 21 is formed on the first electrode 10.

### Embodiment 2

In the present embodiment, the processes performed up until forming a plurality of wells 61 are the same as the processes of the first embodiment, thus the description will begin with the subsequent process steps.

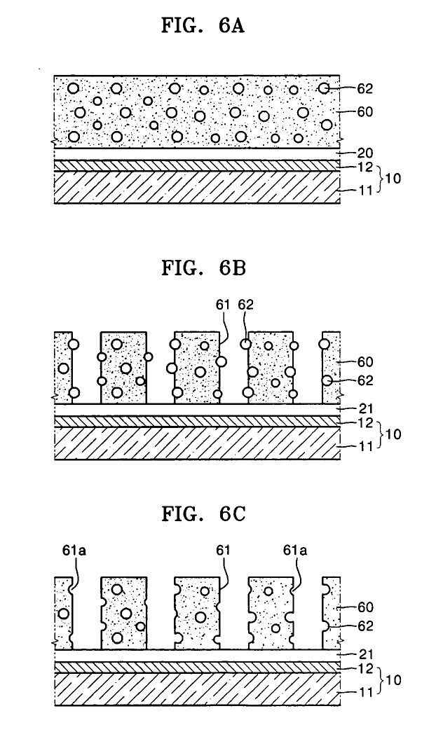

Referring to FIG. 5A, fine particles or balls 62, which are soluble in a solvent, are injected into the wells 61 of the template layer 60. The particles or balls 62 have a size smaller than the diameter of the wells 61 and are formed of polystyrene or silica. In order to inject the balls 62 into the wells 61, the balls 62 are distributed in a solution, and the solution is injected into the wells 61 using a spin coating process, a doctor blade process, a screen printing process, or capillarity action. After the balls 62 are injected, the solution is removed using a drying process.

Referring to FIG. 5B, an oxide semiconductor material 22 is filled in the wells 61. For this, a TiCl₄ solution is brought into contact with the base 21, which is exposed in the bottoms of the wells 61, for about 3 hours so that rods 22 fixed onto the base 21 are formed due to hydrolysis. Thereafter, the resultant structure is precipitated and then annealed at a temperature of about 50° C. for about 2 hours.

Referring to FIG. 5C, the template layer 60 and the balls 62 are removed, thereby forming an oxide semiconductor layer 20, which includes the base 21 and the plurality of rods 22 that are vertically fixed to the base 21. Also, after the template layer 60 is removed, post-treatment is required. For example, after the template layer 60 is dissolved in a solvent (e.g., NaOH) and removed, the resultant structure may be cleaned using deionized water and then thermally treated in an appropriate method. Also, the removal of the balls 62 is performed using an additional solvent. For instance, polystyrene balls are removed using an organic solvent, such as acetone, while silica balls are removed using an HF-containing acidic solution. After these processes are performed, the rods 22 are thermally treated at a temperature of about 100° C. for about 30 minutes.

### Embodiment 3

In the present embodiment, the processes performed up until forming a base 21 are the same as the processes of the first embodiment, thus the description begins with the subsequent process steps.

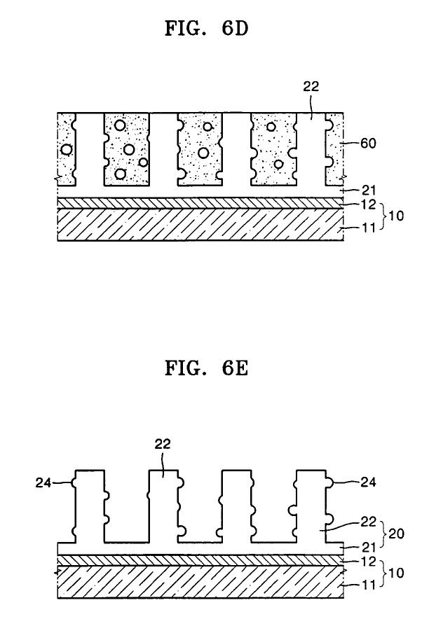

Referring to FIG. 6A, a template layer 60 is formed on the base 21. The template layer 60 is formed to a thickness of, for example, 20 microns, using a spin coating process or other thick layer forming processes such as a spin coating process, a doctor blade process, or a printing process. The template layer 60 may be formed of a material that is soluble in a certain solvent. For example, the template layer 60 may be formed of a photoresist material such as AAM, PMMA, or PC, which is mixed with particles or balls 62 formed of polystyrene or silica. The template layer 60 and the balls 62 should have a selectivity with respect to a certain solvent. Thus, the balls 62 are distributed in the template layer 60 as shown in FIG. 6A.

Referring to FIG. 6B, a plurality of wells 61 are formed in the template layer 60 such that the surface of the base 21 is exposed in the bottoms of the wells 61. The wells 61 are formed to a diameter of about 20 to 200 nm using, for example, a photolithography process or an e-beam lithography process. While the wells 61 are being formed, some balls 62 are removed and the other balls 62 remain lodged in the inner walls of the wells 61.

Referring to FIG. 6C, the balls 62 remaining in the wells 61 are removed using an organic solvent or an HF-containing acid, which dissolves the balls 62. As the balls 62 are removed, a plurality of cavities 61a are formed in the inner walls of the wells 61.

Referring to FIG. 6D, an oxide semiconductor material 22 is filled in the wells 61 using the same material and process steps as described in the first and second embodiments. As a result, the oxide semiconductor material 22 is filled also in the cavities 61a formed in the inner walls of the wells 61.

Referring to FIG. 6E, the template layer 60 is removed in the same manner as described in the first and second embodiments, thereby forming an oxide semiconductor layer 20, which includes the base 21 and the plurality of rods 22 that are vertically fixed to the base 21. During the removal of the template layer 60, the balls 61 distributed in the template layer 60 are removed at the same time. In the above-described process, the oxide semiconductor layer 20 having the plurality of rods 21 is formed on the first electrode 10. In the present embodiment, a plurality of protrusions 24 are formed on the entire outer surfaces of the rods 22 so that the rods 22 have increased surface areas.

According to the present invention as explained thus far, an electron transfer layer (i.e., an oxide semiconductor layer) is structurally improved so that electron transfer efficiency can be enhanced. Also, owing to the increased surface area of the oxide semiconductor layer, photoelectric conversion efficiency can be elevated.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A photovoltaic cell comprising:
a first electrode and a second electrode disposed opposite each other and spaced a predetermined distance apart from each other; and
an oxide semiconductor layer interposed between the first and second electrodes and disposed on the first electrode,
wherein the oxide semiconductor layer includes a base and a plurality of rods, each of which vertically extends from the base and provides fine apertures, and the base and the rods are integrally formed.

2. The photovoltaic cell according to claim 1, wherein the base and the rods of the oxide semiconductor layer are formed of the same material.

3. The photovoltaic cell according to claim 1, wherein each of the rods has a porous structure and the surface has a plurality of cavities.

4. The photovoltaic cell according to claim 1, wherein a plurality of protrusions are formed on the surface of each of the rods.

5. The photovoltaic cell according to claim 1, wherein an electrolytic solution is interposed between the oxide semiconductor layer and the second electrode.

6. The photovoltaic cell according to claim 3, wherein an electrolytic solution is interposed between the oxide semiconductor layer and the second electrode.

7. The photovoltaic cell according to claim 4, wherein an electrolytic solution is interposed between the oxide semiconductor layer and the second electrode.

8. The photovoltaic cell according to claim 1, wherein the first electrode includes:
a first substrate; and
a first transparent conductive layer disposed on one surface of the first substrate,
and the second electrode includes:
a second substrate;
a second transparent conductive layer disposed on one surface of the second substrate; and
a noble metal thin layer disposed on an inner surface of the second transparent conductive layer.

9. The photovoltaic cell according to claim 8, wherein the base and the rods are formed of one selected from the group consisting of SnO₂, TiO₂, and ZnO.

10. The photovoltaic cell according to claim 1, wherein the base and the rods are formed of a transition metal oxide selected from the group consisting of SnO₂, TiO₂, and ZnO.

11. A method of manufacturing a photovoltaic cell, the method comprising:
forming a transparent conductive layer on a substrate;
forming a base on the transparent conductive layer using an oxide semiconductor material to a predetermined thickness;
forming a template layer on the base, the template layer having a plurality of wells that expose the surface of the base;
forming a plurality of rods in the wells by filling an oxide semiconductor material in the wells; and
forming an oxide semiconductor layer by removing the template layer, the oxide semiconductor layer including the rods formed on the base.

12. The method according to claim 11, wherein the template layer is formed of a photoresist material.

13. The method according to claim 11, further comprising:
injecting fine particles or balls into the wells before forming the rods in the wells; and
removing the fine particles or balls together while removing the template layer.

14. The method according to claim 11, wherein the forming of the template layer comprises forming the template layer using a material containing a plurality of distributed fine particles or balls.

15. The method according to claim 13, wherein the fine particles or balls are formed of one of polystyrene and silica.

16. The method according to claim 14, wherein the fine particles or balls are formed of one of polystyrene and silica.

17. The method according to claim 13, wherein after removing the template layer, the fine particles or balls are removed in a further process step.

18. The method according to claim 14, wherein while removing the template layer, the fine particles or balls are removed at the same time.
